(19) United States
(12) Patent Application Publication
(10) Pub. No.: US 2019/0103462 A1
(43) Pub. Date: Apr. 4, 2019

(54) SILICON CARBIDE SEMICONDUCTOR DEVICE

(71) Applicant: FUJI ELECTRIC CO., LTD., Kawasaki (JP)

(72) Inventor: Shinichiro MATSUNAGA, Matsumoto (JP)

(73) Assignee: FUJI ELECTRIC CO., LTD., Kawasaki (JP)

(21) Appl. No.: 16/119,246

(22) Filed: Aug. 31, 2018

(30) Foreign Application Priority Data
Oct. 3, 2017 (JP) 2017-193856

(51) Int. Cl. H01L 29/16; H01L 29/36; H01L 29/868; H01L 29/70; H01L 29/167; H01L 29/32; H01L 21/02; H01L 21/04; H01L 29/06; H01L 21/78; H01L 29/66

(52) U.S. Cl. CPC H01L 29/1608; H01L 29/6606; H01L 29/868; H01L 29/70; H01L 29/167; H01L 29/32; H01L 21/02378; H01L 21/02529; H01L 21/0262; H01L 21/02634; H01L 21/02576; H01L 21/02579; H01L 21/0475; H01L 29/0615; H01L 21/78; H01L 29/36

(57) ABSTRACT

For example, a pin diode is constituted by a silicon carbide epitaxial substrate in which silicon carbide epitaxial layers constituting an n-type buffer region, an n⁻-type drift region, and a p⁺⁺-type anode region are sequentially formed by epitaxial growth on a front surface of an n⁺-type silicon carbide substrate. The n⁻-type drift region has an n-type impurity concentration is, for example, about 1×10¹⁴/cm³ to 1×10¹⁶/cm³. The n⁻-type drift region has a boron concentration that is substantially lower than an n-type impurity concentration of the n⁻-type drift region and that, for example, is about 1×10¹⁴/cm³ or less. During epitaxial growth of the n⁻-type drift region, automatic doping of boron to the n⁻-type drift region is suppressed, whereby the boron concentration of the n⁻-type drift region is reduced and the n⁻-type drift region in which no traps are present is formed.

### CROSS REFERENCE TO RELATED APPLICATIONS

This application is based upon and claims the benefit of priority of the prior Japanese Patent Application No. 2017-193856, filed on Oct. 3, 2017, the entire contents of which are incorporated herein by reference.

### BACKGROUND

### 1. Field

Embodiments of the invention relate to a silicon carbide semiconductor device.

### 2. Description of Related Art

Silicon carbide (SiC) is chemically a very stable semiconductor material, has a wide bandgap of 3 eV, and can be used very stably as a semiconductor even at high temperatures. Silicon carbide has a critical electric field strength that is ten times that of silicon or greater, and is expected to be a semiconductor material that can sufficiently reduce ON-resistance. Therefore, semiconductor devices (hereinafter, silicon carbide semiconductor devices) that use silicon carbide are capable of withstanding high voltages and constitute various application-specific commercial products. Breakdown voltage is a voltage limit at which no errant operation or damage of an element occurs.

A silicon carbide semiconductor device is fabricated (manufactured) using a silicon carbide epitaxial substrate in which a silicon carbide epitaxial layer is formed by epitaxial growth on a starting substrate (hereinafter, silicon carbide substrate) containing silicon carbide. A structure of the conventional silicon carbide semiconductor device will be described. FIG. 4 is a cross-sectional view of a structure of a conventional silicon carbide semiconductor device. The conventional silicon carbide semiconductor device depicted in FIG. 4 is, for example, a p-intrinsic-n (pin) diode fabricated using a silicon carbide epitaxial substrate 110.

The silicon carbide epitaxial substrate 110 is formed by sequentially forming by epitaxial growth on an n⁺-type silicon carbide substrate 101 constituting an n⁺-type cathode region, silicon carbide epitaxial layers 102, 103 constituting an n-type buffer region and an n⁻-type drift region. In a surface layer on a first side of the n⁻-type drift region (the silicon carbide epitaxial layer 103), opposite a second side thereof facing toward the n⁺-type silicon carbide substrate 101, a p⁺⁺-type anode region 104 is provided. Reference numerals 105, 106 are an anode electrode and a cathode electrode, respectively.

In general, in a silicon carbide semiconductor device, a higher breakdown voltage may be sustained and impurity concentrations of regions may be increased as compared to a semiconductor device in which silicon is used. Nonetheless, to sustain breakdown voltages of 13 kV or higher, a low impurity concentration of the n⁻-type drift region of about 5×10¹⁴/cm³ or less is necessary. When the impurity concentration of the n⁻-type drift region is reduced in this way, the carrier concentration of the n⁻-type drift region is also reduced. The higher is the breakdown voltage, the higher is the ON resistance.

Further, with the conventional silicon carbide semiconductor device, in the silicon carbide epitaxial layer 103 constituting the n⁻-type drift region, numerous traps (defects mainly capturing electrons and vacancies (indicated by “x” in drawing)) 111 forming an energy level (defect level: hereinafter, trap level) trapping carriers are present. Due to these traps 111, the carrier concentration of the n⁻-type drift region decreases and therefore, voltage (forward voltage) during forward operation increases and the ON resistance increases.

Therefore, in the conventional silicon carbide semiconductor device, even with a bipolar device in which the carrier concentration of the n⁻-type drift region may be increased during forward operation by conductivity modulation effect, decreases in the carrier concentration of the n⁻-type drift region due to the traps 111 and increases in the ON resistance due to decreases in the carrier concentration cannot be avoided. Therefore, to obtain low ON resistance characteristics close to ideal characteristics of silicon carbide, the traps 111 in the n⁻-type drift region have to be reduced.

A trap level due to the traps 111 includes a trap level of silicon carbide and as the trap level of silicon carbide, various defect levels formed by defects caused by carbon atom vacancies are known. For example, a commonly known point defect called a Z_{1/2} center exists in the n-type silicon carbide epitaxial layers 102, 103 and is a very typical defect caused by carbon atom vacancies. A Z_{1/2} center is a trap that forms an electron trap level (energy level that captures electrons) at an energy level that is deeper than a bottom of a conduction band.

With epitaxial growth by general conditions, defects caused by carbon atom vacancies are introduced into the silicon carbide epitaxial layers 102, 103 at a high density of about 1×10¹³/cm³ and forward characteristics of the diode degrade. Therefore, many cases have been reported in which forward characteristics of the diode are improved by a method of supplying carbon atoms in the silicon carbide epitaxial layers 102, 103 and performing heat treatment to thereby reduce the defects that are caused by carbon atom vacancies.

For example, as a method of reducing defects caused by carbon atom vacancies, the following two methods have been proposed. The first method is a method of diffusing carbon atoms that are ion implanted in the silicon carbide epitaxial layer 103. The carbon atoms are diffused from an ion implantation surface of the silicon carbide epitaxial layer 103 to a deep region by heat treatment. The second method is a method of forming an oxide film (not depicted) on the silicon carbide epitaxial layer 103 by thermal oxidation and releasing excess carbon atoms occurring near an interface of the oxide film into the silicon carbide epitaxial layer 103.

By these methods, even after epitaxial growth of the silicon carbide epitaxial layer 103, carbon atoms are compensated in the silicon carbide epitaxial layer 103 (n⁻-type drift region), defects caused by carbon atom vacancies in the n⁻-type drift region are reduced, whereby forward characteristics of the diode are improved.

As a conventional silicon carbide semiconductor device, a device has been proposed in which a part of or the entire drift region is a high concentration layer that includes donors and acceptors (for example, refer to Japanese Laid-Open Patent Publication No. 2016-213473 (paragraph 0017)). In Japanese Laid-Open Patent Publication No. 2016-213473, due to the high concentration layer in which a sum of a donor concentration and an acceptor concentration is 1×10¹⁸/cm³ or higher, expansion of stacking faults in the drift region is suppressed. Additionally, an absolute value of a difference of the donor concentration and the acceptor concentration is in a range from 5×10¹⁴/cm³ to 1×10¹⁷/cm³ and a significant decrease in breakdown voltage is suppressed.

Further, as a method of forming an n⁻-type silicon carbide epitaxial layer of a low impurity concentration, a method has been proposed in which, an n⁻-type silicon carbide epitaxial layer is formed by epitaxial growth under a condition of a lower nitrogen concentration in an epitaxial growth furnace (for example, refer to Japanese Laid-Open Patent Publication No. 2015-143168 (paragraphs 0067 to 0069)). In Japanese Laid-Open Patent Publication No. 2015-143168, a nitrogen concentration of a member constituting an epitaxial growth furnace is reduced and/or a flowrate of nitrogen gas introduced in the epitaxial growth furnace is adjusted, whereby the nitrogen taken in by the n⁻-type silicon carbide epitaxial layer during epitaxial growth is reduced.

Further, as another method of forming an n⁻-type silicon carbide epitaxial layer of a low impurity concentration, a method has been proposed in which the epitaxial growth furnace is constituted by a member subject to nitrogen desorption by vacuum baking, and nitrogen released from the epitaxial growth furnace is reduced (for example, refer to Japanese Laid-Open Patent Publication No. 2015-050436 (paragraphs 0028 to 0029)). In Japanese Laid-Open Patent Publication No. 2015-050436, by sufficient desorption of the nitrogen from a replacement member of the epitaxial growth furnace by vacuum baking, the nitrogen released from the replacement member is reduced.

### SUMMARY

According to an embodiment, a silicon carbide semiconductor device includes a semiconductor substrate of a first conductivity type and containing silicon carbide; a first semiconductor region provided on a surface of the semiconductor substrate and constituted by a silicon carbide crystal layer of the first conductivity type and having an impurity concentration lower than an impurity concentration of the semiconductor substrate; and a second semiconductor region of a second conductivity type provided on a first side of the first semiconductor region, opposite a second side of the first semiconductor region facing toward the semiconductor substrate, the second semiconductor region forming a pn junction with the first semiconductor region. An impurity concentration of a first impurity of the first conductivity type of the first semiconductor region is at most 1×10¹⁶/cm³. An impurity concentration of boron that is a second impurity different from the first impurity of the first conductivity type of the first semiconductor region is lower than the impurity concentration of the first impurity of the first conductivity type of the first semiconductor region and is at most 1×10¹⁴/cm³.

In the embodiment, the second semiconductor region, the first semiconductor region, and the semiconductor substrate constitute a diode.

In the embodiment, the second semiconductor region, the first semiconductor region, and the semiconductor substrate constitute a diode included in a bipolar device.

In the embodiment, the bipolar device is any one of a bipolar transistor, an insulated gate bipolar transistor, and a thyristor.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view of a silicon carbide semiconductor device according to an embodiment;

FIG. 2 is a characteristics diagram of simulation results of relationships between operating voltage during forward operation and current density;

FIG. 3 is a table of operating voltage values at a predetermined current density in FIG. 2; and

FIG. 4 is a cross-sectional view of a structure of a conventional silicon carbide semiconductor device.

### DESCRIPTION OF EMBODIMENTS

First, problems associated with the conventional techniques will be described. In a device designed for high voltages and to have an n⁻-type drift region that has a low impurity concentration, when other traps exist in the n⁻-type drift region even when defects caused by carbon atom vacancies (Z_{1/2} center, etc.) are reduced, a problem arises in that the ON resistance characteristics degrade.

Embodiments of a silicon carbide semiconductor device according to the present invention will be described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −, and represents one example. In the description of the embodiments below and the accompanying drawings, main portions that are identical will be given the same reference numerals and will not be repeatedly described.

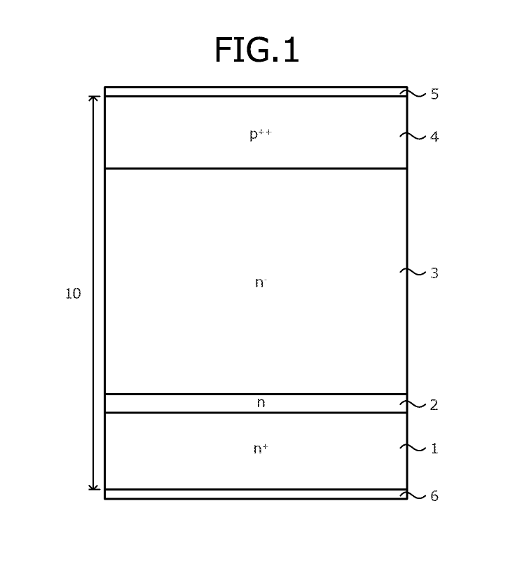

A structure of the silicon carbide semiconductor device according to the embodiment will be described. FIG. 1 is a cross-sectional view of the silicon carbide semiconductor device according to the embodiment. The silicon carbide semiconductor device according to the embodiment and depicted in FIG. 1, is for example, a silicon carbide (SiC) pin diode that uses a silicon carbide epitaxial substrate (semiconductor chip) 10. In a silicon carbide epitaxial substrate 10, silicon carbide epitaxial layers (silicon carbide crystal layers) constituting an n-type buffer region 2, an n⁻-type drift region 3, and a p⁺⁺-type anode region 4 are sequentially formed by epitaxial growth on a front surface of a starting substrate (n⁺-type silicon carbide substrate) 1 containing an n⁺-type silicon carbide.

The n⁺-type silicon carbide substrate 1 is an n⁺-type cathode region. The n⁺-type silicon carbide substrate 1 has an impurity concentration that may be, for example, about 1×10¹⁹/cm³. The n-type buffer region 2 is a dislocation conversion layer that suppresses propagation of stacking faults generated and originating from basal plane dislocations (BPDs) of the n⁺-type silicon carbide substrate 1, to the n⁻-type drift region 3. The n-type buffer region 2 has function of converting with high efficiency, basal plane dislocations propagated to the n⁻-type drift region 3 from the n⁺-type silicon carbide substrate 1 accompanying epitaxial growth, into threading edge dislocations that do not generate stacking faults. The n⁻-type drift region 3 may be provided on the front surface of the n⁺-type silicon carbide substrate 1 without providing the n-type buffer region 2.

The n⁻-type drift region 3 is a breakdown voltage region for sustaining a predetermined breakdown voltage of the silicon carbide semiconductor device and constitutes an intrinsic semiconductor layer (i-type: intrinsic) layer of a pin diode. The n⁻-type drift region 3 has an n-type impurity concentration that is, for example, in a range from about 1×10¹⁴/cm³ to 1×10¹⁶/cm³. The n⁻-type drift region 3 has an n-type impurity concentration and a thickness that varies according to the breakdown voltage and, for example, in a case of 1200V, are about 1×10¹⁶/cm³ or less and about 10 μm or higher, respectively. Further, the n-type impurity concentration and the thickness of the n⁻-type drift region 3, for example, in a case of 20 kV are 4×10¹⁴/cm³ or less and about 150 μm or greater, respectively.

The n⁻-type drift region 3, as described hereinafter, is formed in a state in which a measure is taken so that boron addition (automatic doping) during epitaxial growth is suppressed. A reason for this is that boron atoms present in the n⁻-type drift region 3 are a factor that increases the ON resistance during forward operation. The ON resistance is element resistance at the time of forward current flow between the anode and cathode. In particular, a boron (B) concentration of the n⁻-type drift region 3 is sufficiently lower than the n-type impurity concentration of the n⁻-type drift region 3 and, for example, is about 1×10¹⁴/cm³ or less.

The p⁺⁺-type anode region 4 may be a diffusion region formed by ion implantation in a surface layer (surface layer on a first side of the n⁻-type drift region 3, opposite a second side thereof facing toward the n⁺-type silicon carbide substrate 1) on a front surface of the silicon carbide epitaxial substrate 10. The p⁺⁺-type anode region 4 has an impurity concentration that is set sufficiently higher than an impurity concentration of the n⁻-type drift region 3. In particular, the impurity concentration of the p⁺⁺-type anode region 4 may be, for example, about 1×10¹⁶/cm³ or higher. The p⁺⁺-type anode region 4 has a thickness that may be, for example, in a range of about 0.1 μm to a few μm.

The impurity concentration and the thickness of the p⁺⁺-type anode region 4 is set so that decreases in the breakdown voltage due to punchthrough to a front electrode 5 does not occur. A reason for this is as follows. For example, when the impurity concentration of the p⁺⁺-type anode region 4 is not sufficiently higher than that of the n⁻-type drift region 3 and the thickness of the p⁺⁺-type anode region 4 is thin, a depletion layer that spreads from a pn junction of the p⁺⁺-type anode region 4 and the n⁻-type drift region 3 during reverse operation may punchthrough to the front electrode 5 and the breakdown voltage may decrease.

The front electrode 5 is in contact with and electrically connected to the p⁺⁺-type anode region 4. The front electrode 5 is an anode electrode. A rear electrode 6 is in contact with a rear surface (rear surface of the n⁺-type silicon carbide substrate 1) of the silicon carbide epitaxial substrate 10 and is electrically connected to the n⁺-type silicon carbide substrate 1 that is the n⁺-type cathode region. The rear electrode 6 is a cathode electrode. In FIG. 1, only an active region responsible for current driving is depicted and an edge termination region surrounding a periphery of the active region is not depicted. The edge termination region is a region that mitigates electric field toward a front surface of the silicon carbide epitaxial substrate 10 and sustains the breakdown voltage.

A method of manufacturing the silicon carbide semiconductor device according to the embodiment will be described. First, the n⁺-type silicon carbide substrate (support wafer) 1 is prepared, the n⁺-type silicon carbide substrate 1 is cleaned by a general semiconductor substrate cleaning method (organic cleaning method, RCA cleaning method, etc.). Next, the n⁺-type silicon carbide substrate 1 is inserted in an epitaxial growth furnace (chamber (not depicted)). Next, a source gas, a carrier gas, and a doping gas, etc. are introduced into the epitaxial growth furnace, and the silicon carbide epitaxial substrate (semiconductor wafer) 10 is fabricated in which silicon carbide epitaxial layers constituting the n-type buffer region 2, the n⁻-type drift region 3, and the p⁺⁺-type anode region 4 are sequentially formed by epitaxial growth.

At this time, as the source gas, a gas containing silicon (Si) and a gas containing carbon (C) are introduced. The gas containing silicon may be, for example, a monosilane (SiH₄) gas. The gas containing carbon, for example, may be a propane (C₃H₈) gas. As the carrier gas, for example, a hydrogen (H₂) gas may be used. As an n-type doping gas, for example, a phosphine (PH₃) gas or an arsine (AsH₃) gas may be used. As a p-type doping gas, for example, trimethylaluminum (Al(CH₃)₃) gas may be used.

Further, during epitaxial growth of an n⁻-type silicon carbide epitaxial layer constituting the n⁻-type drift region 3, a measure for suppressing unintended boron addition (automatic doping) to the n⁻-type silicon carbide epitaxial layer is taken. As a result, the n⁻-type drift region 3 may be formed in which substantially no defects due to carbon atom vacancies (for example, electron traps such as Z_{1/2} centers, etc.) or hole traps (energy levels capturing holes) due to boron are present. Boron is a light element and automatic doping of boron to the n⁻-type silicon carbide epitaxial layer cannot be avoided. Therefore, to suppress the addition of boron to the n⁻-type drift region 3 during epitaxial growth, for example, one or more of the following measures is taken.

A first measure is use of a member (susceptor, quartz tube, etc.) having an ultrahigh purity (for example, a purity of about 6N(=99.9999%) or 9N (=99.9999999%)) and containing minimal boron to reduce the boron released in the atmosphere in the epitaxial growth furnace. A second measure is use of a gas having an ultrahigh purity and containing minimal boron, whereby boron included in the gas introduced in the epitaxial growth furnace is reduced. A third measure is sufficiently performing “aging” or “preheat treatment” (heat treatment), etc. in the epitaxial growth furnace to reduce the boron released from the member in the epitaxial growth furnace into the atmosphere.

After the n⁻-type silicon carbide epitaxial layer constituting the n⁻-type drift region 3 is formed by epitaxial growth, similar to a conventional method, carbon atoms may be supplied in the n⁻-type drift region 3 and heat treatment may be performed to reduce in the n⁻-type drift region 3, defects caused by carbon atom vacancies.

Next, by photolithography and etching, the p⁺⁺-type silicon carbide epitaxial layer constituting the p⁺⁺-type anode region 4 is selectively removed and in the edge termination region, the n⁻-type drift region 3 is exposed at the front surface of the silicon carbide epitaxial substrate 10. When the p⁺⁺-type anode region 4 is selectively formed by ion implantation, in the edge termination region, the n⁻-type drift region 3 is already exposed at the front surface of the silicon carbide epitaxial substrate 10 and therefore, etching is not performed.

Next, in the edge termination region, for example, a breakdown voltage structure such as a guard ring, RESURF, etc. for mitigating the electric field strength in a lateral direction (direction parallel to the front surface of the silicon carbide epitaxial substrate 10) is formed. Next, on the front and rear surfaces of the silicon carbide epitaxial substrate 10, the front electrode 5 and the rear electrode 6 are formed respectively. Thereafter, the semiconductor wafer is diced (cut) into individual chip, whereby the pin diode depicted in FIG. 1 and including the n-type buffer region 2 is completed.

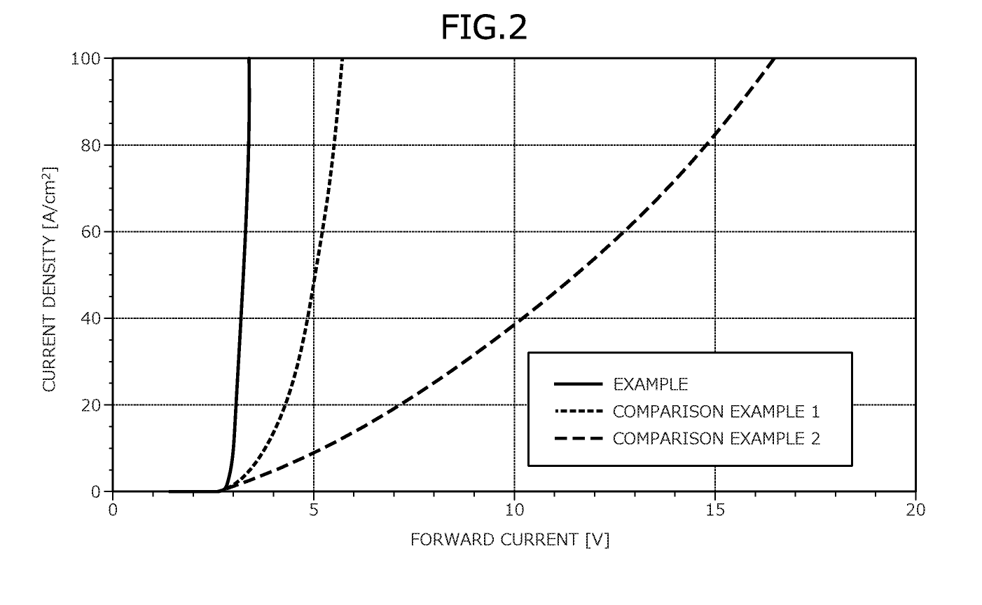

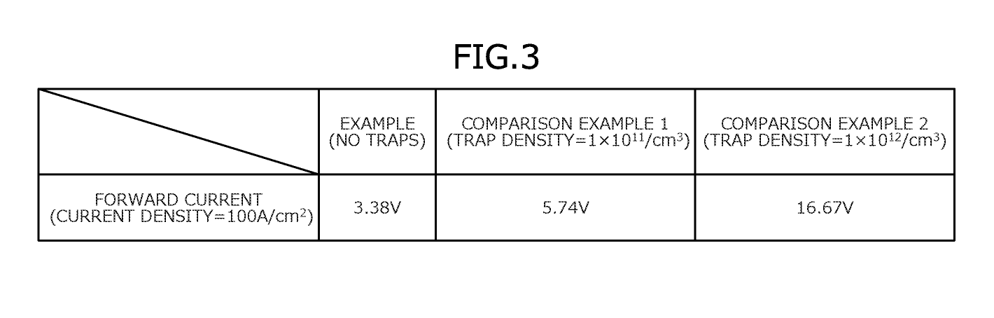

Operating voltage (forward voltage) during forward operation of the silicon carbide semiconductor device according to the embodiment was verified. FIG. 2 is a characteristics diagram of simulation results of relationships between operating voltage during forward operation and current density. FIG. 3 is a table of operating voltage values at a predetermined current density in FIG. 2. FIG. 3 depicts the operating voltages (forward voltage) when Example and comparison examples 1, 2 are forward operated at the same current density (=100 A/cm²).

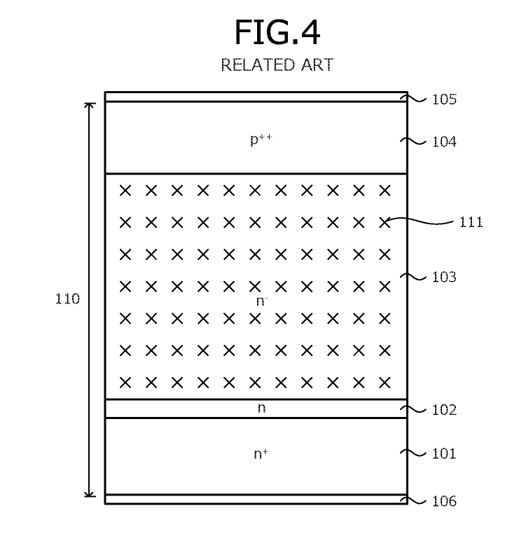

Simulation results of the relationship between the forward voltage and current density of the pin diode (hereinafter, Example) including the silicon carbide semiconductor device according to the embodiment (refer to FIG. 1) are depicted in FIG. 2. Further, in FIG. 2, for comparison, simulations results of the relationship between the forward voltage and current density of a pin diode (hereinafter, comparison examples 1, 2) that includes the conventional silicon carbide semiconductor device (refer to FIG. 4) are depicted.

In Example, traps are substantially not present in the n⁻-type drift region 3 (trap density in the n⁻-type drift region 3≈0/cm³). In comparison example 1, traps are introduced at a trap density of about 1×10¹¹/cm³ in the n⁻-type drift region (the silicon carbide epitaxial layer 103). In comparison example 2, traps are introduced at a trap density of about 1×10¹²/cm³ in the n⁻-type drift region. Here, the traps are electron traps and hole traps. The breakdown voltage of Example and comparison examples 1, 2 was 13 kV.

The results depicted in FIG. 2 confirm that in Example and in comparison examples 1, 2, the higher is the current density, the greater the forward voltage increases. However, for Example, it was confirmed that increases in the forward voltage were suppressed compared to comparison examples 1, 2. For example, as depicted in FIG. 3, during operation at a current density of 100 A/cm², the forward voltage of Example was 3.38V whereas the forward voltages of comparison examples 1, 2 were 5.74V and 16.67V, respectively.

In other words, in comparison examples 1, 2, the lower is the trap density in the n⁻-type drift region, the amount of increase in the forward voltage with respect to the magnitude of the current density may be reduced. However, compared to Example, the amount of increase in the forward voltage is large and conduction loss is large. By establishing a state in which traps substantially are not present in the n⁻-type drift region 3 like in Example, increases in the forward voltage may be suppressed and the conduction loss may be reduced.

As described, according to the embodiment, automatic doping of boron in the n⁻-type drift region is suppressed, boron concentration in the n⁻-type drift region is sufficiently lower than the n-type impurity concentration and, for example, may be is set to be about 1×10¹⁴/cm³ or less. In this manner, the boron concentration of the n⁻-type drift region is extremely low, whereby hole traps caused by boron atoms are not introduced into the n⁻-type drift region. Therefore, decreases of minority carriers (holes) in the n⁻-type drift region during bipolar operation (during forward operation of the diode) may be suppressed. In addition, during bipolar operation, indirect recombination of electrons due to hole traps is suppressed and decreases in majority carriers (electrons) of the n⁻-type drift region may be suppressed. In other words, during bipolar operation, decreases of the carrier concentration of the n⁻-type drift region may be suppressed and the conduction resistance (ON resistance) may be reduced. Therefore, low ON resistance characteristics close to ideal characteristics based on characteristics for silicon carbide as the semiconductor material may be obtained. Further, according to the embodiment, adverse effects of the hole traps during high-temperature operation decrease and therefore, compared to low-temperature operation, negative temperature characteristics of the ON resistance during high-temperature operation becoming smaller are improved.

Further, according to the embodiment, when forward current of a current density equal to that of a conventional structure flows, the forward voltage at the time of bipolar operation may be reduced more than that with the conventional structure and the conduction loss may be reduced. Therefore, a silicon carbide semiconductor device capable of bipolar operation at a high current density in a state in which the ON resistance is maintained may be provided.

In the embodiments of the present invention, various modifications within a range not departing from the spirit of the invention are possible. For example, dimensions, impurity concentrations, etc. of regions may be variously set according to required specifications. Further, the present invention is applicable to parasitic pin diodes built in unipolar devices such as metal oxide semiconductor field effect transistors (MOSFETs). Further, the present invention is applicable to bipolar transistors, insulated gate bipolar transistors (IGBTs), bipolar devices such as thyristors, etc.

The silicon carbide semiconductor device according to the embodiments of the present invention achieves an effect in that decreases in the carrier concentration of the n⁻-type drift region may be suppressed and therefore, the ON resistance characteristics during bipolar operation (during forward operation of the diode) may be improved.

As described, the silicon carbide semiconductor device according to the embodiments of the present invention is useful for high-voltage (about 1200V or higher) silicon carbide semiconductor devices and is particularly suitable for bipolar silicon carbide semiconductor devices.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A silicon carbide semiconductor device comprising:
a semiconductor substrate of a first conductivity type and containing silicon carbide;
a first semiconductor region provided on a surface of the semiconductor substrate and constituted by a silicon carbide crystal layer of the first conductivity type and having an impurity concentration lower than an impurity concentration of the semiconductor substrate; and
a second semiconductor region of a second conductivity type provided on a first side of the first semiconductor region, opposite a second side of the first semiconductor region facing toward the semiconductor substrate, the second semiconductor region forming a pn junction with the first semiconductor region, wherein
an impurity concentration of a first impurity of the first conductivity type of the first semiconductor region is at most 1×10¹⁶/cm³, and
an impurity concentration of boron that is a second impurity different from the first impurity of the first conductivity type of the first semiconductor region is lower than the impurity concentration of the first impurity of the first conductivity type of the first semiconductor region and is at most 1×10¹⁴/cm³.

2. The silicon carbide semiconductor device according to claim 1, wherein
the second semiconductor region, the first semiconductor region, and the semiconductor substrate constitute a diode.

3. The silicon carbide semiconductor device according to claim 1, wherein
the second semiconductor region, the first semiconductor region, and the semiconductor substrate constitute a diode included in a bipolar device.

4. The silicon carbide semiconductor device according to claim 3,
the bipolar device is any one of a bipolar transistor, an insulated gate bipolar transistor, and a thyristor.
